(19) United States
(12) Patent Application Publication
(10) Pub. No.: US 2026/0353886 A1
(43) Pub. Date: Nov. 5, 2026

(54) DISPLAY DEVICE

(71) Applicant: LG Display Co., Ltd., Seoul (KR)

(72) Inventor: Yongmin JEONG, Paju-si (KR)

(73) Assignee: LG Display Co., Ltd., Seoul (KR)

(21) Appl. No.: 19/660,556

(22) Filed: Apr. 28, 2026

(30) Foreign Application Priority Data
Apr. 30, 2025 (KR) 10-2025-0057238

(51) Int. Cl. H10H 29/45; H10F 39/00; H10H 20/819; H10H 29/49

(52) U.S. Cl. CPC H10H 29/45; H10F 39/80373; H10H 20/819; H10H 29/49

(57) ABSTRACT

A display device is provided with a first gate electrode disposed under a semiconductor layer, a second gate electrode disposed on the semiconductor layer, and at least one source electrode electrically connected to the semiconductor layer. The first gate electrode and the second gate electrode do not overlap.

### CROSS-REFERENCE TO RELATED APPLICATIONS

This application claims the benefit of and priority to Korean Patent Application No. 10-2025-0057238 filed on Apr. 30, 2025, the entire contents of which are incorporated herein by reference for all purposes.

### BACKGROUND

### 1. Technical Field of Technology

The present disclosure relates to a display device.

### 2. Description of the Related Art

The display device is applied to various electronic devices such as TVs, mobile phones, laptops, and tablets.

The display devices include an organic light emitting display (OLED) that emit light by themselves and a liquid crystal display (LCD) that require a separate light source.

Various display devices are utilized as display apparatuses, including an organic light emitting display OLED that emits light by itself, a liquid crystal display LCD that requires a separate light source, and a light emitting diode display device including a light emitting diode LED.

Recently, research has been conducted on a stretchable display device capable of stretching in a specific direction and changing into various shapes. Meanwhile, due to the structure of the stretchable display device, the stretchable display device may include a transparent region. Accordingly, the stretchable display device has a problem in that visibility is reduced by external front light and rear light.

The description of related art should not be considered prior art merely because it is mentioned in or associated with this section. The description of related art includes information that describes one or more aspects of the subject technology, and the description in this section does not limit the scope of the present disclosure.

### SUMMARY

The present disclosure addresses one or more problems in the related art, including the foregoing problems, and an aspect of the present disclosure provides a display device including a photo detector capable of detecting light in both directions.

In accordance with an aspect of the present disclosure, the above and other technical effects can be accomplished by the provision of a display device comprising a display area including a plurality of subpixels, wherein each of the plurality of subpixels includes a light emitting device configured to emit light and a photo detector configured to detect light, wherein the photo detector includes a semiconductor layer, at least one first gate electrode disposed under the semiconductor layer, at least one second gate electrode disposed on the semiconductor layer, at least one source electrode electrically connected to the semiconductor layer, and a drain electrode electrically connected to the semiconductor layer, and wherein the at least one first gate electrode and the at least one second gate electrode do not overlap.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a perspective view schematically illustrating a display device according to an embodiment of the present disclosure.

FIG. 2 is a plan view enlarging a portion of the display area of FIG. 1.

FIG. 3 is a circuit diagram of one sub-pixel according to an embodiment of the present disclosure.

FIG. 4 is a circuit diagram of one sub-pixel according to another embodiment of the present disclosure.

FIG. 5 is a cross-sectional view of a display device according to an embodiment of the present disclosure.

FIGS. 6 and 7 are cross-sectional views illustrating an operation of a photo detector according to an embodiment of the present disclosure.

FIG. 8 is a cross-sectional view of a display device according to another embodiment of the present disclosure.

FIGS. 9 and 10 are cross-sectional views illustrating an operation of a photo detector according to another embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where “comprise,” “have” and “include” described in the present disclosure are used, another portion may be added unless “only~” is used. The terms of a singular form may include plural forms unless referred to the contrary. In one or more examples, unless expressly stated otherwise, an element may be one or more elements; and an element may include a plurality of elements.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In construing an element, the element is construed as including an error band although there is no explicit description. Any implementation described herein as an “example” is not necessarily to be construed as preferred or advantageous over other implementations.

In describing a position relationship, for example, when the position relationship is described as “upon~,” “above~,” “below~” and “next to~,” one or more portions may be disposed between two other portions unless “just” or “direct” is used. The terms, such as “below,” “lower,” “above,” “upper” and the like, may be used herein to describe a relationship between element(s) as illustrated in the drawings. It will be understood that the terms are spatially relative and based on the orientation depicted in the drawings.

It will be understood that, although the terms “first,” “second,” “A,” “B,” “(a),” and “(b)” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element. Further, unless stated otherwise, “at least some,” “some,” “at least some elements,” “one or more,” or the like of a plurality of elements can represent (i) one element of the plurality of elements, (ii) a portion of the plurality of elements, (iii) one or more portions of the plurality of elements, (iv) one or more elements of the plurality of elements, (v) multiple elements of the plurality of elements, or (vi) all of the plurality of elements. Moreover, unless stated otherwise, “at least some,” “some,” or the like of an element can represent (i) a portion of the element, (ii) one or more portions of the element, (iii) the element, or (iv) all portions of the element.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, one or more embodiments of the present disclosure will be described in detail with reference to the accompanying drawings.

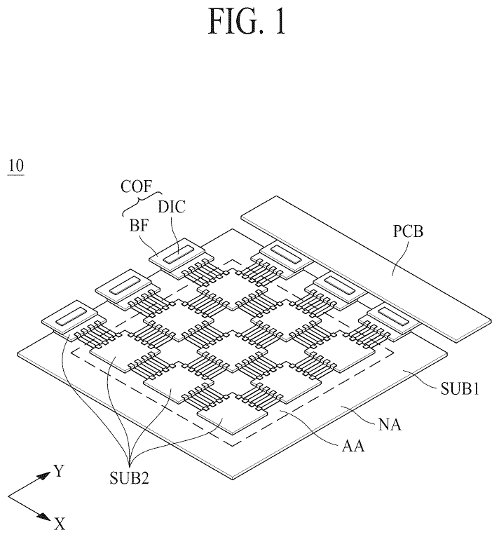

FIG. 1 is a perspective view schematically illustrating a display device 10 according to an embodiment of the present disclosure.

The display device 10 may be a stretchable display device. In this case, the display device 10 can be stretched in either a first direction X or a second direction Y. Alternatively, the display device 10 can be stretched two-dimensionally along both the first direction X and the second direction Y. Here, the first direction X and the second direction Y define a plane of the display device 10, and the second direction Y may be perpendicular to the first direction X.

Referring to FIG. 1, the display device 10 may include a first substrate SUB1, a plurality of second substrates SUB2, connection lines CL, a chip-on-film COF, and a printed circuit board PCB. In addition, the display device 10 may further include a third substrate disposed on an upper portion of the first substrate SUB1, but is not limited thereto.

The first substrate SUB1 may be a substrate configured to support and protect various components of the display device 10. In addition, the first substrate SUB1 may be a flexible substrate.

The first substrate SUB1 may include a transparent insulation material. In addition, the first substrate SUB1 may include an insulation material that can be bent or stretched. For example, the first substrate SUB1 may include a silicone rubber, such as polydimethylsiloxane (PDMS), or an elastomer such as polyurethane (PU), but is not limited thereto.

The first substrate SUB1 may include a display area AA and a non-display area NA surrounding the display area AA.

The display area AA may be an area for displaying an image. The display area AA may include a plurality of pixels. In addition, light emitting elements and various driving elements configured to drive the light emitting elements may be disposed in the plurality of pixels.

The non-display area NA may be an area that does not display an image. Various wirings and circuit components may be disposed in the non-display area NA.

The plurality of second substrates SUB2 may be spaced apart from each other and disposed on the first substrate SUB1. The plurality of second substrates SUB2 may be arranged in a matrix form including a plurality of rows and columns, but is not limited thereto.

The plurality of second substrates SUB2 may be relatively rigid compared to the first substrate SUB1. That is, the first substrate SUB1 may have flexible characteristics relative to the plurality of second substrates SUB2, and the plurality of second substrates SUB2 may have rigid characteristics relative to the first substrate SUB1.

The plurality of second substrates SUB2 may include a plastic material having flexibility. For example, the plurality of second substrates SUB2 may include polyimide (PI), polyacrylate, or polycerate, but is not limited thereto.

The connection lines CL may be disposed between the plurality of second substrates SUB2. The connection lines CL are disposed between pads disposed on the plurality of second substrates SUB2 and may electrically connect the respective pads.

The chip-on-film COF may supply signals to the display area AA. Specifically, the chip-on-film COF may be electrically connected to the plurality of pads disposed in the non-display area NA. Through the plurality of pads, the chip-on-film COF may supply various voltages to the plurality of sub-pixels in the display area AA.

The chip-on-film COF may include a base film BF and a driving IC DIC. The base film BF is an insulating material having flexibility and may support the driving IC DIC. The driving IC DIC may generate data for displaying the image and driving signals for processing the data.

The printed circuit board PCB may generate signals for driving the plurality of sub-pixels. The printed circuit board PCB may be electrically connected to the plurality of sub-pixels through the chip-on-film COF. The printed circuit board PCB may have a control unit including an IC chip and a driving circuit. Alternatively, the printed circuit board PCB may include a memory and a processor.

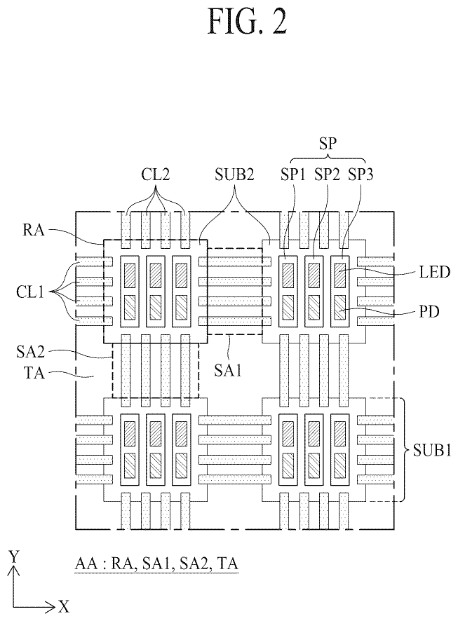

FIG. 2 is a plan view enlarging a portion of the display area AA of FIG. 1.

The display area AA may include a rigid area RA, a first stretchable area SA1, a second stretchable area SA2, and a transmissive area TA.

The rigid area RA may be an area where the plurality of second substrates SUB2 are disposed. A plurality of sub-pixels SP may disposed in each of the plurality of second substrates SUB2. A first sub-pixel SP1, a second sub-pixel SP2, and a third sub-pixel SP3 are disposed in one of the plurality of second substrate SUB2.

FIG. 2 is disclosed that the first sub-pixel SP1, the second sub-pixel SP2, and the third sub-pixel SP3 are arranged along the first direction X, but is not limited thereto. In addition, the first sub-pixel SP1 may emit red light, the second sub-pixel SP2 may emit green light, and the third sub-pixel SP3 may emit blue light, but is not limited thereto.

Each of the plurality of sub-pixels SP may include a light emitting device LED and a photo detector PD. The light emitting device LED generates light and emits light externally, and the photo detector PD may detect external light. On one second substrate SUB2, the light emitting device LED and the photo detector PD may be spaced apart from each other.

The connection lines CL may include a first connection line CL1 and a second connection line CL2.

The first connection line CL1 may be disposed along the first direction X. The first connection line CL1 may electrically connect pads disposed on two second substrates SUB2 that are adjacent in the first direction X. In addition, the second connection line CL2 may electrically connect pads disposed on two second substrates SUB2 that are adjacent in the second direction Y.

Through the pads, the first connection line CL1 and the second connection line CL2 may transfer various signals to the plurality of sub-pixels. That is, the first connection line CL1 and the second connection line CL2 may transfer various signals to the light emitting devices LED and the photo detectors PD disposed in the plurality of sub-pixels. For example, the first connection line CL1 or the second connection line CL2 may transfer a gate signal, a data signal, and a common voltage, but is not limited thereto.

Each of the first connection line CL1 and the second connection line CL2 may include a base polymer and conductive particles. Similar to the first substrate SUB1, the base polymer may include an insulating material that can be bent or stretched. Accordingly, even when the display device 10 is bent or stretched, the base polymer may not be damaged. The conductive particles may be dispersed within the base polymer. The conductive particles may form conductive paths electrically connecting pads disposed on adjacent second substrates SUB2.

As described above, since the first substrate SUB1 and the connection lines CL include materials having flexible characteristics, an area where the first substrate SUB1 and the connection lines CL are disposed may function as a stretchable area. Accordingly, an area where the first connection line CL1 is disposed may be the first stretchable area SA1, and an area where the second connection line CL2 is disposed may be the second stretchable area SA2.

Since the first connection line CL1 is disposed between two second substrates SUB2 adjacent in the first direction X, the first stretchable area SA1 may be disposed between rigid areas RA that are adjacent in the first direction X. In addition, since the second connection line CL2 is disposed between two second substrates SUB2 adjacent in the second direction Y, the second stretchable area SA2 may be disposed between rigid areas RA that are adjacent in the second direction Y. Furthermore, any one of the rigid areas RA may be disposed between adjacent first flexible areas SA1 and between adjacent second stretchable areas SA2. That is, the light emitting devices LED and the photo detectors PD may be disposed between first connection lines CL1 that are adjacent to each other and between second connection lines CL2 that are adjacent to each other.

The transmissive area TA may be an area excluding the rigid areas RA and the stretchable areas SA. The transmissive area TA may be an area where the plurality of second substrates SUB2 and the connection lines CL are not disposed. That is, only the first substrate SUB1 may be disposed in the transmissive area TA. In addition, the light emitting devices LED and the photo detectors PD may be disposed only in the rigid areas RA and may not be disposed in the stretchable areas SA or the transmissive area TA.

As described above, since the first substrate SUB1 is made of a transparent material, external light may pass through the transmissive area TA. In particular, external light incident from a front surface of the display device 10 and external light incident from a rear surface of the display device 10 may both pass through the transmissive area TA.

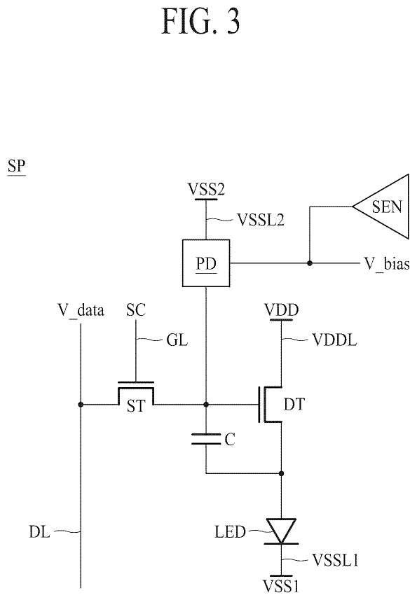

FIG. 3 is a circuit diagram of one sub-pixel SP according to an embodiment of the present disclosure.

Referring to FIG. 3, one sub-pixel SP may include a driving transistor DT, a switching transistor ST, a capacitor C, a light emitting device LED, a photo detector PD, and a sensing unit SEN.

The driving transistor DT may be disposed between a high-potential voltage line VDDL and the light emitting device LED. The driving transistor DT may control a driving current. Specifically, the driving transistor DT may control a current flowing from the high-potential voltage line VDDL to the light emitting device LED according to the voltage difference between a gate electrode and a source electrode of the driving transistor DT.

A gate electrode of the driving transistor DT may be connected to a first electrode of the switching transistor ST. A first electrode (source electrode or drain electrode) of the driving transistor DT may be connected to an anode of the light emitting device LED, and a second electrode (drain electrode or source electrode) may be connected to the high-potential voltage line VDDL to which a high-potential voltage VDD is supplied.

The switching transistor ST may be driven by a scan signal SC of a gate line GL. When the switching transistor ST is turned on by the scan signal SC, the switching transistor ST may transfer a data voltage V_data of a data line DL to the gate electrode of the driving transistor DT.

In addition, a gate electrode of the switching transistor ST may be connected to the gate line GL, a first electrode may be connected to the gate electrode of the driving transistor DT, and a second electrode may be connected to the data line DL.

The capacitor C may be disposed between the gate electrode and the source electrode of the driving transistor DT. The capacitor C may store a voltage difference between the gate voltage and the source voltage of the driving transistor DT.

FIG. 2 disclose that the driving transistor DT and the switching transistor ST are formed as N-type MOSFETs (Metal Oxide Semiconductor Field Effect Transistors), but is not limited thereto. For example, the driving transistor DT and the switching transistor ST may be P-type MOSFETs.

In addition, the first electrode may be a source electrode and the second electrode may be a drain electrode, but is not limited thereto. For example, the first electrode may be a drain electrode and the second electrode may be a source electrode.

The light emitting device LED may emit light according to a current supplied through the driving transistor DT. An anode of the light emitting device LED may be connected to the source electrode of the driving transistor DT, and a cathode of the light emitting device LED may be connected to a first low-potential voltage line VSSL1 to which a first low-potential voltage VSS1 is supplied. The first low-potential voltage VSS1 may be lower than the high-potential voltage ELVDD.

When the light emitting device LED is a light emitting diode (LED), holes and electrons may combine in an active layer each other when a voltage is applied to the n-electrode and the p-electrode. Accordingly, the light emitting device LED may emit light.

A first electrode of the photo detector PD may be connected to a bias voltage V_bias, a second electrode of the photo detector PD may be connected to a second low-potential voltage line VSSL2 to which a second low-potential voltage VSS2 is supplied, and a third electrode of the photo detector PD may be connected to the gate electrode of the driving transistor DT. The second low-potential voltage VSS2 may be lower than the high-potential voltage ELVDD. In addition, the second low-potential voltage VSS2 may be the same as or different from the first low-potential voltage VSS1.

The sensing unit SEN may be connected to the first electrode of the photo detector PD. The sensing unit SEN may sense a current of the first electrode of the photo detector PD. When external light is incident on (or in) the photo detector PD, an intensity of the current at the first electrode of the photo detector PD may vary. In this case, the sensing unit SEN may detect an intensity of the external light incident on (or in) the sub-pixel SP by sensing the intensity of the current variation at the first electrode of the photo detector PD.

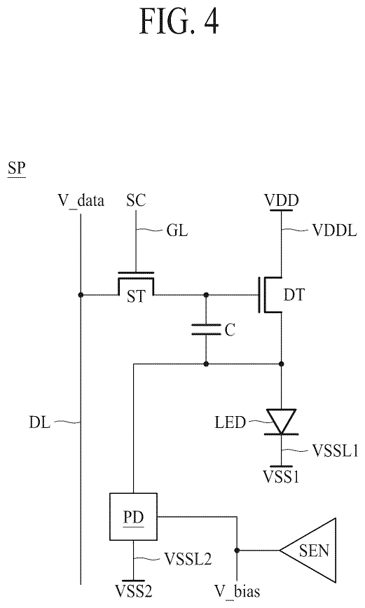

FIG. 4 is a circuit diagram of one sub-pixel SP according to another embodiment of the present disclosure.

Compared to FIG. 3, FIG. 4 discloses substantially the same structure as FIG. 3, except for the connection structure of the photo detector PD. Therefore, the same reference numerals are used for components identical to those of the display device shown in FIG. 3, and repetitive descriptions are omitted.

As described above, one sub-pixel SP may include the driving transistor DT, the switching transistor ST, the capacitor C, the light emitting device LED, the photo detector PD, and the sensing unit SEN.

Referring to FIG. 4, the first electrode of the photo detector PD may be connected to the bias voltage V_bias, the second electrode of the photo detector PD may be connected to the second low-potential voltage line VSSL2 to which the second low-potential voltage VSS2 is supplied, and the third electrode of the photo detector PD may be connected to the first electrode of the driving transistor DT. The second low-potential voltage VSS2 may be lower than the high-potential voltage ELVDD. In addition, the second low-potential voltage VSS2 may be the same as or different from the first low-potential voltage VSS1.

As described above with reference to FIG. 3, the sensing unit SEN may be connected to the first electrode of the photo detector PD. The sensing unit SEN may sense the current of the first electrode of the photo detector PD. When external light is incident on (or in) the photo detector PD, the intensity of the current at the first electrode of the photo detector PD may vary. In this case, the sensing unit SEN may detect the intensity of the external light incident on the sub-pixel SP by sensing the intensity of the current variation at the first electrode of the photo detector PD.

FIGS. 3 and 4 disclose that the sub-pixel SP includes a circuit having a 2T1C structure with two transistors and one capacitor, but is not limited thereto. For example, the sub-pixel SP may include three or more transistors or two or more capacitors.

Although not shown in FIGS. 3 and 4, a control circuit or a compensation circuit electrically connected to the sub-pixel SP may be additionally formed. For example, based on a current corresponding to external light detected by the photo detector PD, the control circuit or the compensation circuit may control a voltage of the driving transistor DT or adjust a luminance of the light emitting device LED, but is not limited thereto. In addition, various circuits using the current corresponding to the external light detected by the photo detector PD, or using the current as data, may be further included, but are not limited thereto.

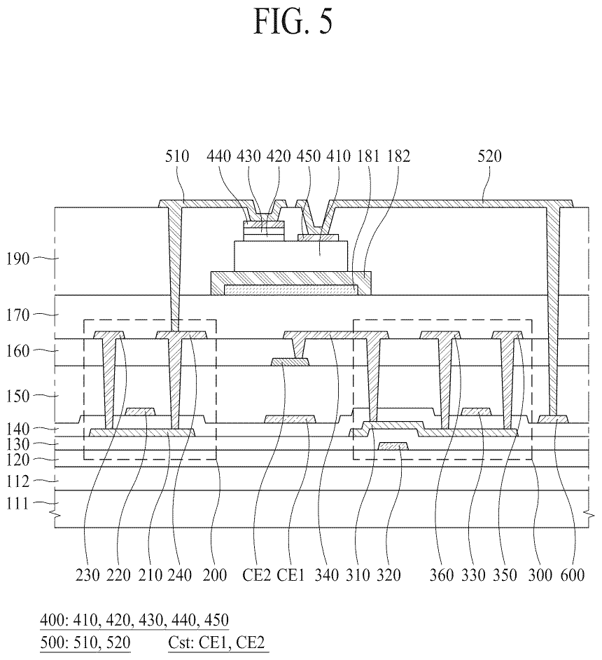

FIG. 5 is a cross-sectional view of the display device 10 according to an embodiment of the present disclosure. In particular, FIG. 5 illustrates the rigid area RA of the display device 10.

Referring to FIG. 5, the display device 10 may include a first substrate 111, a second substrate 112, a buffer layer 120, a first gate insulating layer 130, a second gate insulating layer 140, a first insulating layer 150, a second insulating layer 160, a first planarization layer 170, a reflective layer 181, an adhesive layer 182, a second planarization layer 190, a driving transistor 200, a photo detector 300, a light emitting device 400, a connection electrode 500, a common line 600, and a capacitor Cst.

The first substrate 111 may include a transparent insulating material. In addition, the first substrate 111 may include an insulating material that can be bent or stretched. For example, the first substrate 111 may include a silicone rubber, such as polydimethylsiloxane (PDMS), or an elastomer such as polyurethane (PU), but is not limited thereto.

The second substrate 112 may be disposed on the first substrate 111. The second substrate 112 may be relatively rigid compared to the first substrate 111. That is, the first substrate 111 may have flexible characteristics relative to the second substrate 112, and the second substrate 112 may have rigid characteristics relative to the first substrate 111.

The second substrate 112 may include a plastic material having flexibility. For example, the second substrate 112 may include polyimide (PI), polyacrylate, or polycerate, but is not limited thereto.

The buffer layer 120 may be disposed on the second substrate 112. The buffer layer 120 may protect various components of the display device 10 from penetration of external moisture and oxygen. The buffer layer 120 may include an insulating material such as silicon nitride (SiNx), silicon oxide (SiOx), or silicon oxynitride (SiON), but is not limited thereto.

The driving transistor 200 may be disposed on the buffer layer 120. The driving transistor 200 may include a semiconductor layer 210, a gate electrode 220, a source electrode 230, and a drain electrode 240.

The semiconductor layer 210 of the driving transistor 200 may be disposed on the buffer layer 120. The semiconductor layer 210 may include at least one oxide of IGZO (indium-gallium-zinc-oxide), IZO (indium-zinc-oxide), IGTO (indium-gallium-tin-oxide), and IGO (indium-gallium-oxide), but is not limited thereto.

The gate electrode 220 of the driving transistor 200 may be disposed on the semiconductor layer 210 of the driving transistor 200. To insulate the gate electrode 220 from the semiconductor layer 210 of the driving transistor 200, the second gate insulating layer 140 may be disposed between the gate electrode 220 and the semiconductor layer 210. The gate electrode 220 may include a metal material such as Au, W, Pt, Si, Ir, Ag, Cu, Ni, Ti, or Cr.

In addition, FIG. 5 disclose that a top-gate structure in which the gate electrode 220 of the driving transistor 200 is disposed on the semiconductor layer 210 of the driving transistor 200, but is not limited thereto. For example, a bottom-gate structure in which the gate electrode 220 of the driving transistor 200 is disposed below the semiconductor layer 210 may be disclosed.

The source electrode 230 and the drain electrode 240 of the driving transistor 200 may face each other and be disposed on the semiconductor layer 210 of the driving transistor 200. Through contact holes disposed in the second gate insulating layer 140, the first insulating layer 150, and the second insulating layer 160, the source electrode 230 and the drain electrode 240 of the driving transistor 200 may contact and be electrically connected to the semiconductor layer 210.

The photo detector 300 may be disposed on the buffer layer 120. The photo detector 300 may include a semiconductor layer 310, a first gate electrode 320, a second gate electrode 330, a first source electrode 340, a second source electrode 350, and a drain electrode 360.

The semiconductor layer 310 of the photo detector 300 may be disposed on the buffer layer 120. The semiconductor layer 310 may include at least one oxide selected from IGZO (indium-gallium-zinc-oxide), IZO (indium-zinc-oxide), IGTO (indium-gallium-tin-oxide), and IGO (indium-gallium-oxide), but is not limited thereto.

The first gate electrode 320 of the photo detector 300 may be disposed below the semiconductor layer 310 of the photo detector 300. To insulate the first gate electrode 320 from the semiconductor layer 310, the first gate insulating layer 130 may be disposed between the first gate electrode 320 and the semiconductor layer 310.

That is, in the photo detector 300, the first gate electrode 320 may be disposed on the buffer layer 120, the first gate insulating layer 130 may be disposed on the first gate electrode 320, and the semiconductor layer 310 may be disposed on the first gate insulating layer 130.

The first gate insulating layer 130 may extend under the driving transistor 200 and be disposed under the semiconductor layer 210 of the driving transistor 200.

The second gate electrode 330 of the photo detector 300 may be disposed on the semiconductor layer 310 of the photo detector 300. To insulate the second gate electrode 330 from the semiconductor layer 310, the second gate insulating layer 140 may be disposed between the second gate electrode 330 and the semiconductor layer 310.

That is, in the photo detector 300, the second gate insulating layer 140 may be disposed on the semiconductor layer 310, and the second gate electrode 330 may be disposed on the second gate insulating layer 140.

In the photo detector 300, each of the first gate electrode 320 and the second gate electrode 330 may overlap with the semiconductor layer 310. However, the first gate electrode 320 and the second gate electrode 330 may not overlap each other. The first gate electrode 320 and the second gate electrode 330 may include a metal material such as Au, W, Pt, Si, Ir, Ag, Cu, Ni, Ti, or Cr.

The first source electrode 340, the second source electrode 350, and the drain electrode 360 of the photo detector 300 may be disposed on the semiconductor layer 310 of the photo detector 300. Through contact holes formed in the second gate insulating layer 140, the first insulating layer 150, and the second insulating layer 160, the first source electrode 340, the second source electrode 350, and the drain electrode 360 of the photo detector 300 may contact and be electrically connected to the semiconductor layer 310.

In the photo detector 300, the first source electrode 340 may be disposed on one side of the first gate electrode 320, and the drain electrode 360 may be disposed on the other side of the first gate electrode 320. In addition, the drain electrode 360 may be disposed on one side of the second gate electrode 330, and the second source electrode 350 may be disposed on the other side of the second gate electrode 330. That is, the drain electrode 360 may be disposed between the first gate electrode 320 and the second gate electrode 330.

In the photo detector 300, the first gate electrode 320 may be disposed between the first source electrode 340 and the drain electrode 360, and the second gate electrode 330 may be disposed between the second source electrode 350 and the drain electrode 360.

In the photo detector 300, the first source electrode 340 may overlap one side of the semiconductor layer 310, the second source electrode 350 may overlap the other side of the semiconductor layer 310, and the drain electrode 360 may overlap a central area of the semiconductor layer 310.

The first gate insulating layer 130 may be disposed on the buffer layer 120. The first gate insulating layer 130 may cover the first gate electrode 320 of the photo detector 300.

The second gate insulating layer 140 may be disposed on the first gate insulating layer 130. The second gate insulating layer 140 may cover the semiconductor layer 210 of the driving transistor 200 and the semiconductor layer 310 of the photo detector 300.

The first gate insulating layer 130 and the second gate insulating layer 140 may be configured as a single layer or a multilayer including silicon nitride (SiNx) or silicon oxide (SiOx).

The first insulating layer 150 may be disposed on the second gate insulating layer 140. The first insulating layer 150 may cover the gate electrode 220 of the driving transistor 200 and the second gate electrode 330 of the photo detector 300.

The second insulating layer 160 may be disposed on the first insulating layer 150. The source electrode 230 and the drain electrode 240 of the driving transistor 200 may be disposed on the second insulating layer 160. In addition, the first source electrode 340, the second source electrode 350, and the drain electrode 360 of the photo detector 300 may be disposed on the second insulating layer 160.

The first insulating layer 150 and the second insulating layer 160 may be formed of an inorganic insulating material such as silicon nitride (SiNx) or silicon oxide (SiOx). Alternatively, the first insulating layer 150 and the second insulating layer 160 may be formed of an organic insulating material such as an acryl resin, epoxy resin, phenolic resin, polyamide resin, or polyimide resin.

The first planarization layer 170 may be disposed on the second insulating layer 160. The first planarization layer 170 may cover the source electrode 230 and the drain electrode 240 of the driving transistor 200. In addition, the first planarization layer 170 may cover the first source electrode 340, the second source electrode 350, and the drain electrode 360 of the photo detector 300. The first planarization layer 170 may compensate for step differences caused by the driving transistor 200 and the photo detector 300, thereby planarizing upper areas of the driving transistor 200 and the photo detector 300.

The first planarization layer 170 may be formed of an organic insulating material such as an acryl resin, epoxy resin, phenolic resin, polyamide resin, or polyimide resin.

The reflective layer 181 may be disposed on the first planarization layer 170. The reflective layer 181 may reflect light generated by the light emitting device 400, which is directed toward the first substrate 111, toward an upper direction of the display device 10. The reflective layer 181 may include a metal material having high reflectivity.

The adhesive layer 182 may be disposed on the reflective layer 181. Through the adhesive layer 182, the light emitting device 400 may be fixed to the reflective layer 181 and insulated from the reflective layer 181.

The light emitting device 400 may be disposed on the adhesive layer 182. The light emitting device 400 may overlap the reflective layer 181 and the adhesive layer 182.

The light emitting device 400 may be a light emitting diode or a micro LED. The light emitting device 400 may include an n-type semiconductor layer 410, an active layer 420, a p-type semiconductor layer 430, a p-type electrode 440, and an n-type electrode 450. In addition, FIG. 5 disclose that the light emitting device 400 is a light-emitting diode having a lateral structure, but it is not limited thereto.

The n-type semiconductor layer 410 may overlap the reflective layer 181 on the adhesive layer 182. The n-type semiconductor layer 410 may be formed of an n-GaN-based semiconductor material such as GaN, AlGaN, InGaN, or AlInGaN. In addition, impurities such as Si, Ge, Se, Te, or C may be used for doping the n-type semiconductor layer 410.

The active layer 420 may be disposed on the n-type semiconductor layer 410. The active layer 420 may be a layer that generates light. The active layer 420 may have a multi-quantum well MQW structure including a well layer and a barrier layer with a bandgap higher than a bandgap of the well layer. For example, the active layer 420 may have a multi-quantum well structure such as InGaN/GaN, but it is not limited thereto.

The p-type semiconductor layer 430 may be disposed on the active layer 420. The p-type semiconductor layer 430 may be formed of a p-GaN-based semiconductor material such as GaN, AlGaN, InGaN, or AlInGaN. In addition, impurities such as Mg, Zn, or Be may be used for doping the p-type semiconductor layer 430.

The p-type electrode 440 may be disposed on the p-type semiconductor layer 430, and the n-type electrode 450 may be disposed on the n-type semiconductor layer 410. The p-type electrode 440 and the n-type electrode 450 may be spaced apart from each other. The p-type electrode 440 and the n-type electrode 450 may be formed of a metal material or an alloy thereof, such as Au, W, Pt, Si, Ir, Ag, Cu, Ni, Ti, or Cr. Alternatively, the p-type electrode 440 and the n-type electrode 450 may include a transparent conductive material such as ITO (Indium Tin Oxide) or IZO (Indium Zinc Oxide).

The second planarization layer 190 may be disposed on the first planarization layer 170. The second planarization layer 190 may cover the light emitting device 400. The second planarization layer 190 may compensate for the step differences caused by the light emitting device 400 and planarize an upper area of the light emitting device 400.

The second planarization layer 190 may be formed of an organic insulating material such as an acryl resin, epoxy resin, phenolic resin, polyamide resin, or polyimide resin.

The connection electrode 500 may be disposed on the second planarization layer 190. The connection electrode 500 may include a first connection electrode 510 and a second connection electrode 520.

The p-type electrode 440 may be electrically connected to the drain electrode 240 of the driving transistor 200 through the first connection electrode 510. In addition, the n-type electrode 450 may be electrically connected to the common line 600 through the second connection electrode 520. Accordingly, different voltage levels applied to the drain electrode 240 of the driving transistor 200 and the common line 600 may be transferred to the p-type electrode 440 and the n-type electrode 450 through the first connection electrode 510 and the second connection electrode 520, so that the light emitting device 400 may emit light.

The first connection electrode 510 and the second connection electrode 520 may be formed of a transparent conductive material such as ITO (Indium Tin Oxide) or IZO (Indium Zinc Oxide).

The capacitor Cst may be disposed on the second gate insulating layer 140. The capacitor Cst may include a first capacitor electrode CE1 and a second capacitor electrode CE2.

The first capacitor electrode CE1 may be disposed between the second gate insulating layer 140 and the first insulating layer 150. Although not shown in FIG. 5, the first capacitor electrode CE1 may be electrically connected to the gate electrode 220 of the driving transistor 200, but is not limited thereto.

The second capacitor electrode CE2 may be disposed on the first insulating layer 150 and may overlap the first capacitor electrode CE1. The second capacitor electrode CE2 may be electrically connected to the first source electrode 340 of the photo detector 300, but is not limited thereto.

The first capacitor electrode CE1 and the second capacitor electrode CE2 may be applied with different voltages, and since the first insulating layer 150 is disposed between the first capacitor electrode CE1 and the second capacitor electrode CE2. Therefore, capacitance may be formed through the first capacitor electrode CE1, the second capacitor electrode CE2, and the first insulating layer 150.

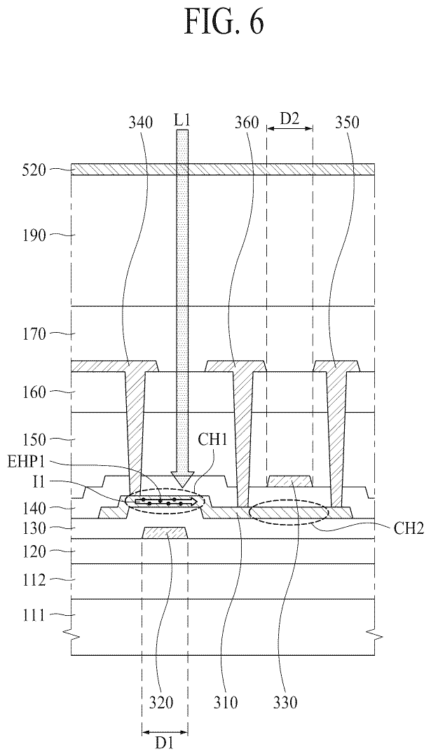

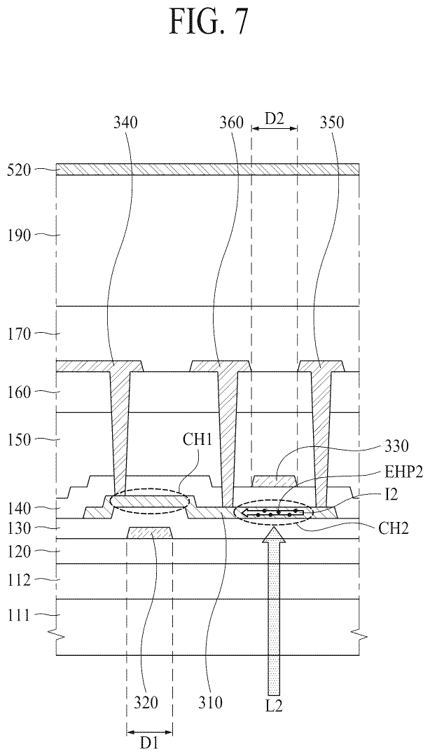

FIGS. 6 and 7 are cross-sectional views illustrating an operation of a photo detector PD according to an embodiment of the present disclosure.

Referring to FIGS. 6 and 7, the photo detector 300 may include a first channel CH1 and a second channel CH2.

The first channel CH1 may be an area that is disposed between the first source electrode 340 and the drain electrode 360 in the semiconductor layer 310 of the photo detector 300. The first channel CH1 may overlap with the first gate electrode 320 on the first gate electrode 320.

The second channel CH2 may be an area that is disposed between the second source electrode 350 and the drain electrode 360 in the semiconductor layer 310 of the photo detector 300. The second channel CH2 may overlap with the second gate electrode 330 under the second gate electrode 330.

Referring to FIG. 6, a first light L1 from an outside of the display device 10 may be incident toward the front surface of the display device 10. As described above, the first insulating layer 150, the second insulating layer 160, the first planarization layer 170, and the second planarization layer 190 may be transparent insulating materials. In addition, the second connection electrode 520 may be a transparent conductive material. Accordingly, the first light L1 can pass through the first insulating layer 150, the second insulating layer 160, the first planarization layer 170, the second planarization layer 190, and the second connection electrode 520.

The first light L1 can pass through the second gate insulating layer 140 and be incident on (or in) the first channel CH1 of the photo detector 300. In this case, a first electron-hole pair EHP1 may be generated in the first channel CH1. When the first electron-hole pair EHP1 is generated, a first current I1 flowing from the first source electrode 340 to the drain electrode 360 of the photo detector 300 may increase. Accordingly, by sensing a fluctuation of the first current I1, an intensity of the first light L1 can be detected.

On the other hand, the first light L1 may not be incident on (or in) the second channel CH2. Specifically, when the first light L1 is directed toward the second channel CH2, the first light L1 can pass through the first insulating layer 150 and be incident on the second gate electrode 330 of the photo detector 300. Since the second gate electrode 330 is made of a metal material, the first light L1 may be reflected by the second gate electrode 330. Accordingly, the first light L1 may not be incident on (or in) the second channel CH2.

Referring to FIG. 7, a second light L2 from the outside of the display device 10 may be directed toward a rear surface of the display device 10. As described above, the first substrate 111, the second substrate 112, and the buffer layer 120 may be made of a transparent insulating material. Accordingly, the second light L2 can pass through the first substrate 111, the second substrate 112, and the buffer layer 120.

The second light L2 can pass through the first gate insulating layer 130 and be incident on (or in) the second channel CH2 of the photo detector 300. In this case, a second electron-hole pair EHP2 may be generated in the second channel CH2. As the second electron-hole pair EHP2 is generated, a second current I2 flowing from the second source electrode 350 to the drain electrode 360 of the photo detector 300 may increase. Accordingly, by sensing a fluctuation of the second current I2, an intensity of the second light L2 can be detected.

In contrast, the second light L2 may not be incident on (or in) the first channel CH1. Specifically, when the second light L2 is directed toward the first channel CH1, the second light L2 may be incident on the first gate electrode 320 of the photo detector 300. Since the first gate electrode 320 is made of a metal material, the second light L2 may be reflected by the first gate electrode 320. Accordingly, the second light L2 may not be incident on (or in) the first channel CH1.

Although not shown in the drawings, in order to further prevent the second light L2 from being incident on (or in) the first channel CH1, a light-blocking layer may be additionally disposed under the first gate electrode 320.

That is, through the first channel CH1, the first light L1 directed toward the front surface of the display device 10 can be detected. In addition, through the second channel CH2, the second light L2 directed toward the rear surface of the display device 10 can be detected.

In this case, the first current I1 caused by the first light L1 flows from the first source electrode 340 to the drain electrode 360, and the second current I2 caused by the second light L2 flows from the second source electrode 350 to the drain electrode 360. That is, the first current I1 and the second current I2 can flow in different directions through different electrodes. Accordingly, the first current I1 and the second current I2 are separated from each other, so the first current I1 and the second current I2 may be individually detected. Therefore, through the first channel CH1 and the second channel CH2 of the photo detector 300, the external light directed toward the front surface and the rear surface of the display device 10 can be respectively detected.

At this time, by adjusting a length D1 of the first gate electrode 320 and a length D2 of the second gate electrode 330, a sensitivity to external light can be controlled. For example, when the length D1 of the first gate electrode 320 is greater than the length D2 of the second gate electrode 330, the sensitivity to light directed toward the front surface of the display device 10 may be higher than the sensitivity to light directed toward the rear surface of the display device 10. In addition, when the length D2 of the second gate electrode 330 is greater than the length D1 of the first gate electrode 320, the sensitivity to light directed toward the rear surface of the display device 10 can be higher than the sensitivity to light directed toward the front surface of the display device 10.

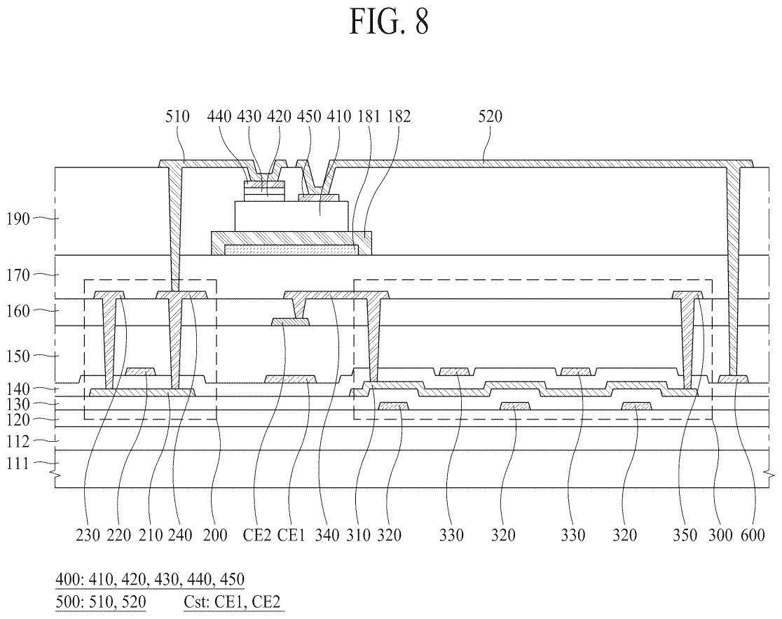

FIG. 8 is a cross-sectional view of a display device according to another embodiment of the present disclosure.

Compared to FIG. 5, except for the structure of the photo detector PD, FIG. 8 discloses a substantially identical structure to that of FIG. 5. Therefore, the same reference numerals are used for components identical to those in the display device shown in FIG. 5, and repeated descriptions are omitted.

Referring to FIG. 8, the photo detector 300 may be disposed on the buffer layer 120. The photo detector 300 may include a semiconductor layer 310, a plurality of first gate electrodes 320, a plurality of second gate electrodes 330, source electrodes 340, and drain electrodes 350.

The semiconductor layer 310 of the photo detector 300 may be disposed on the buffer layer 120. The semiconductor layer 310 of the photo detector 300 may include at least one oxide selected from IGZO (indium-gallium-zinc-oxide), IZO (indium-zinc-oxide), IGTO (indium-gallium-tin-oxide), and IGO (indium-gallium-oxide), but is not limited thereto.

The plurality of first gate electrodes 320 of the photo detector 300 may be disposed under the semiconductor layer 310 of the photo detector 300. The plurality of first gate electrodes 320 may be spaced apart from each other. To insulate the plurality of first gate electrodes 320 from the semiconductor layer 310 of the photo detector 300, the first gate insulating layer 130 may be disposed between the plurality of first gate electrodes 320 and the semiconductor layer 310. In addition, the first gate insulating layer 130 may be disposed between the adjacent first gate electrodes 320.

That is, in the photo detector 300, the plurality of first gate electrodes 320 may be disposed on the buffer layer 120, the first gate insulating layer 130 may be disposed on the plurality of first gate electrodes 320, and the semiconductor layer 310 may be disposed on the first gate insulating layer 130.

The plurality of second gate electrodes 330 of the photo detector 300 may be disposed on the semiconductor layer 310. The plurality of second gate electrodes 330 may be spaced apart from each other. To insulate the plurality of second gate electrodes 330 from the semiconductor layer 310, the second gate insulating layer 140 may be disposed between the plurality of second gate electrodes 330 and the semiconductor layer 310. In addition, the second gate insulating layer 140 may be disposed between the adjacent plurality of second gate electrodes 330.

That is, in the photo detector 300, the second gate insulating layer 140 may be disposed on the semiconductor layer 310, and the plurality of second gate electrodes 330 may be disposed on the second gate insulating layer 140.

In the photo detector 300, each of the plurality of first gate electrodes 320 and the plurality of second gate electrodes 330 may overlap the semiconductor layer 310. However, the plurality of first gate electrodes 320 and the plurality of second gate electrodes 330 may not overlap each other.

The plurality of first gate electrodes 320 and the plurality of second gate electrodes 330 may be arranged alternately. Specifically, any one of the first gate electrodes 320 may be disposed between two adjacent second gate electrodes 330. Similarly, any one of the second gate electrodes 330 may be disposed between two adjacent first gate electrodes 320.

The plurality of first gate electrodes 320 and the plurality of second gate electrodes 330 may include a metal material such as Au, W, Pt, Si, Ir, Ag, Cu, Ni, Ti, or Cr.

In the photo detector 300, the source electrode 340 and the drain electrode 350 may be disposed on the semiconductor layer 310. Through contact holes disposed in the second gate insulating layer 140, the first insulating layer 150, and the second insulating layer 160, the source electrode 340 and the drain electrode 350 may contact and be electrically connected to the semiconductor layer 310 of the photo detector 300.

In the photo detector 300, the source electrode 340 may be disposed on one side of the semiconductor layer 310, and the drain electrode 350 may be disposed on the opposite side of the semiconductor layer 310. The plurality of first gate electrodes 320 and the plurality of second gate electrodes 330 may be disposed between the source electrode 340 and the drain electrode 350.

The first gate insulating layer 130 may be disposed on the buffer layer 120. The first gate insulating layer 130 may cover the plurality of first gate electrodes 320 of the photo detector 300.

The second gate insulating layer 140 may be disposed on the first gate insulating layer 130. The second gate insulating layer 140 may cover the semiconductor layer 310 of the photo detector 300.

The first insulating layer 150 may be disposed on the second gate insulating layer 140. The first insulating layer 150 may cover the plurality of second gate electrodes 330 of the photo detector 300.

The second insulating layer 160 may be disposed on the first insulating layer 150. The source electrode 340 and the drain electrode 350 of the photo detector 300 may be disposed on the second insulating layer 160.

The first planarization layer 170 may be disposed on the second insulating layer 160. The first planarization layer 170 may cover the source electrode 340 and the drain electrode 350 of the photo detector 300.

The capacitor Cst may be disposed on the second gate insulating layer 140. The capacitor Cst may include a first capacitor electrode CE1 and a second capacitor electrode CE2.

The first capacitor electrode CE1 may be disposed between the second gate insulating layer 140 and the first insulating layer 150. Although not shown in FIG. 8, the first capacitor electrode CE1 may be electrically connected to the gate electrode 220 of the driving transistor 200, but is not limited thereto.

The second capacitor electrode CE2 may be disposed on the first insulating layer 150 and may overlap the first capacitor electrode CE1. The second capacitor electrode CE2 may be electrically connected to the source electrode 340 of the photo detector 300, but is not limited thereto.

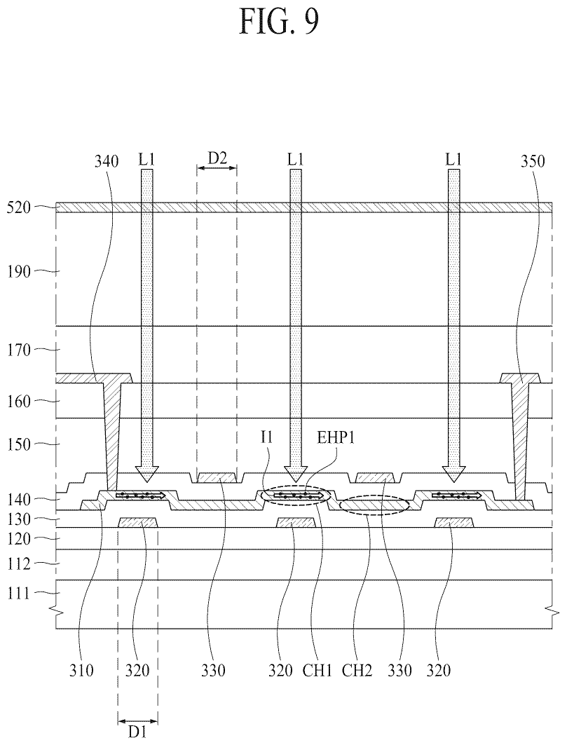

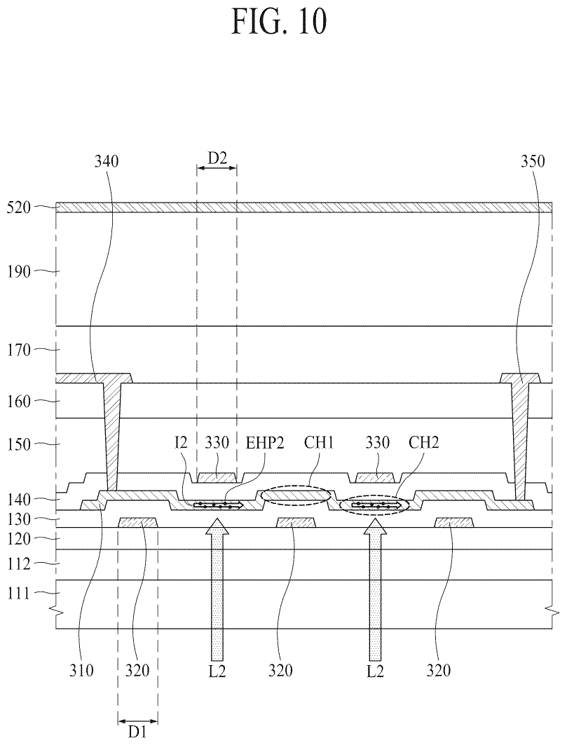

FIGS. 9 and 10 are cross-sectional views illustrating an operation of the photo detector 300 according to another embodiment of the present disclosure.

Referring to FIGS. 9 and 10, the photo detector 300 may include a plurality of first channels CH1 and a plurality of second channels CH2.

The plurality of first channels CH1 may be disposed between the source electrode 340 and the drain electrode 350 in the semiconductor layer 310 of the photo detector 300 and may be overlap the plurality of first gate electrodes 320.

The plurality of second channels CH2 may be disposed between the source electrode 340 and the drain electrode 350 in the semiconductor layer 310 of the photo detector 300 and may be overlap the plurality of second gate electrodes 330.

Referring to FIG. 9, a first light L1 from outside of the display device 10 may be directed toward the front surface of the display device 10. As described above, the first insulating layer 150, the second insulating layer 160, the first planarization layer 170, and the second planarization layer 190 may be transparent insulating materials. In addition, the second connecting electrode 520 may be a transparent conductive material. Accordingly, the first light L1 may pass through the first insulating layer 150, the second insulating layer 160, the first planarization layer 170, the second planarization layer 190, and the second connecting electrode 520.

The first light L1 may pass through the second gate insulating layer 140 and be incident on (or in) the plurality of first channels CH1 of the photo detector 300. In this case, a first electron-hole pair EHP1 may be generated in each of the plurality of first channels CH1. As the first electron-hole pair EHP1 is generated, a first current I1 flowing from the source electrode 340 to the drain electrode 360 of the photo detector 300 may increase. Accordingly, by sensing a fluctuation of the first current I1, an intensity of the first light L1 can be detected.

On the other hand, the first light L1 may not be incident on (or in) the plurality of second channels CH2. Specifically, when the first light L1 is directed toward the second channels CH2, the first light L1 may pass through the first insulating layer 150 and be incident on the plurality of second gate electrodes 330 of the photo detector 300. Since the plurality of second gate electrodes 330 are made of a metal material, the first light L1 may be reflected by the plurality of second gate electrodes 330. Accordingly, the first light L1 may not be incident on (or in) the second channels CH2.

Referring to FIG. 10, a second light L2 from outside of the display device 10 may be directed toward a rear surface of the display device 10. As described above, the first substrate 111, the second substrate 112, and the buffer layer 120 may be made of transparent insulating materials. Accordingly, the second light L2 can pass through the first substrate 111, the second substrate 112, and the buffer layer 120.

The second light L2 may pass through the first gate insulating layer 130 and be incident on (or in) the plurality of second channels CH2 of the photo detector 300. In this case, a second electron-hole pair EHP2 may be generated in each of the plurality of second channels CH2. As the second electron-hole pair EHP2 is generated, a second current I2 flowing from the source electrode 340 to the drain electrode 350 of the photo detector 300 may increase. Accordingly, by sensing a fluctuation of the second current I2, an intensity of the second light L2 can be detected.

On the other hand, the second light L2 may not be incident on (or in) the plurality of first channels CH1. Specifically, when the second light L2 is directed toward the plurality of first channels CH1, the second light L2 may be incident on the plurality of first gate electrodes 320 of the photo detector 300. Since the plurality of first gate electrodes 320 are made of a metal material, the second light L2 may be reflected by the plurality of first gate electrodes 320. Accordingly, the second light L2 may not be incident on (or in) the first channels CH1.

Although not shown in the drawings, to further prevent the second light L2 from being incident on the first channels CH1, a light blocking layer may be additionally disposed under the plurality of first gate electrodes 320.

That is, the first light L1 directed toward the front surface of the display device 10 can be detected through the first channels CH1. In addition, the second light L2 directed toward the rear surface of the display device 10 can be detected through the second channels CH2.

At this time, both the first current I1 generated by the first light L1 and the second current I2 generated by the second light L2 may flow from the source electrode 340 to the drain electrode 350. That is, the first current I1 and the second current I2 can flow in the same direction through the same electrode. Since the first current I1 and the second current I2 flow in the same direction through the same electrode, they can be detected integrally. Accordingly, through the first channels CH1 and the second channels CH2 of the photodetector 300, external light directed toward the front and rear surfaces of the display device 10 can be detected integrally.

The photo detector 300 disclosed in FIGS. 5 to 7 disclose both the first source electrode 340 and the second source electrode 350, whereas the photo detector 300 disclosed in FIGS. 8 to 10 disclose only a single source electrode 340. Accordingly, compared to the photo detector 300 disclosed in FIGS. 5 to 7, the photo detector 300 disclosed in FIGS. 8 to 10 can detect currents generated by external light while reducing the number of electrodes.

In addition, the photo detector 300 in FIGS. 5 to 7 discloses a single first gate electrode 320 and a single second gate electrode 330, whereas the photo detector 300 in FIGS. 8 to 10 discloses the plurality of first gate electrodes 320 and the plurality of second gate electrodes 330. Accordingly, compared to the photo detector 300 disclosed in FIGS. 5 to 7, the lengths of the first channel CH1 and the second channel CH2 in the photo detector 300 disclosed in FIGS. 8 to 10 may be increased. As a result, the areas of the first and second channels CH1 and CH2, where through which external light may be incident, are increase, thereby increasing an amount of light incident on (or in) the photo detector 300.

At this time, by adjusting a length D1 of the first gate electrode 320 and a length D2 of the second gate electrode 330, a sensitivity to external light can be controlled. For example, when the length D1 of the first gate electrode 320 is greater than the length D2 of the second gate electrode 330, the sensitivity to light directed toward the front surface of the display device 10 may be higher than the sensitivity to light directed toward the rear surface of the display device 10. In addition, when the length D2 of the second gate electrode 330 is greater than the length D1 of the first gate electrode 320, the sensitivity to light directed toward the rear surface of the display device 10 can be higher than the sensitivity to light directed toward the front surface of the display device 10.

Alternatively, by controlling the number of first gate electrodes 320 and the number of second gate electrodes 330, a sensitivity to external light can be controlled. In FIGS. 8 to 10, three first gate electrodes 320 and two second gate electrodes 330 are disclosed, but this is not limiting.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device, comprising:
a display area including a plurality of subpixels; and
wherein each of the plurality of subpixels includes a light emitting device configured to emit light and a photo detector configured to detect light,
wherein the photo detector includes:
a semiconductor layer;
at least one first gate electrode disposed under the semiconductor layer;
at least one second gate electrode disposed on the semiconductor layer;
at least one source electrode electrically connected to the semiconductor layer; and
a drain electrode electrically connected to the semiconductor layer, and
wherein the at least one first gate electrode and the at least one second gate electrode do not overlap.

2. The display device of claim 1, further comprising:
a first gate insulating layer disposed between the semiconductor layer and the at least one first gate electrode; and
a second gate insulating layer disposed between the semiconductor layer and the at least one second gate electrode.

3. The display device of claim 1, wherein the at least one source electrode includes a first source electrode and a second source electrode, which are spaced apart from each other.

4. The display device of claim 3, wherein one of the at least one first gate electrode is disposed between the first source electrode and the drain electrode, and
wherein one of the at least one second gate electrode is disposed between the second source electrode and the drain electrode.

5. The display device of claim 3, wherein the drain electrode is disposed between one of the at least one first gate electrode and one of the at least one second gate electrode.

6. The display device of claim 3, wherein the semiconductor layer includes:
a first channel disposed between the first source electrode and the drain electrode; and
a second channel disposed between the second source electrode and the drain electrode,
wherein when light is incident on the first channel, a current flows between the first source electrode and the drain electrode, and
wherein when light is incident on the second channel, a current flows between the second source electrode and the drain electrode.

7. The display device of claim 1, wherein the at least one first gate electrode includes a plurality of first gate electrodes, and the at least one second gate electrode includes a plurality of second gate electrodes, and
wherein the plurality of first gate electrodes and the plurality of second gate electrodes are disposed between the at least one source electrode and the drain electrode.

8. The display device of claim 7, wherein the plurality of first gate electrodes and the plurality of second gate electrodes are alternately arranged.

9. The display device of claim 7, wherein at least one of the plurality of first gate electrodes is disposed between two adjacent second gate electrodes.

10. The display device of claim 7, wherein at least one of the plurality of second gate electrodes is disposed between two adjacent first gate electrodes.

11. The display device of claim 7, wherein the semiconductor layer includes:
a first channel overlapping with at least one of the at least one first gate electrode; and
a second channel overlapping with at least one of the at least one second gate electrode, and
wherein when light is incident on the first channel or the second channel, a current flows between the drain electrode and at least one of the at least one source electrode.

12. The display device of claim 1, further comprising:
a first substrate disposed at least in the display area;
a plurality of second substrates disposed on the first substrate and spaced apart from each other; and
a connection line disposed on the first substrate and disposed between adjacent second substrates,
wherein the plurality of subpixels are disposed on the plurality of second substrates, and
wherein the connection line is configured to transfer a signal to at least some of the plurality of subpixels.

13. The display device of claim 12, wherein the first substrate has greater flexibility than each of the plurality of second substrates.

14. The display device of claim 12, wherein the display area includes:
a rigid area including the plurality of second substrates;
a stretchable area including the connection line; and
a transmissive area being an area excluding the rigid area and the stretchable area.

15. The display device of claim 12, wherein the connection line is configured to transfer a signal to the photo detector.

16. The display device of claim 14, wherein the photo detector is disposed in the rigid area and is not disposed in the stretchable area or the transmissive area.

17. The display device of claim 12, wherein the light emitting device and the photo detector are spaced apart from each other and disposed on a corresponding one of the plurality of second substrates.

18. The display device of claim 12, wherein the photo detector is disposed between adjacent connection lines.

19. The display device of claim 1, wherein the light emitting device is a micro light emitting diode (LED).
